(19) United States
(12) Patent Application Publication
(10) Pub. No.: US 2010/0187101 A1
(43) Pub. Date: Jul. 29, 2010

(54) METHOD OF MANUFACTURING THE SEMICONDUCTOR DEVICE

(75) Inventors: Gil-Sub Kim, Suwon-si (KR); Won-Mo Park, Seongnam-si (KR); Seong-Ho Kim, Seoul (KR); Dong-Kwan Yang, Yongin-si (KR); Ho-Ju Song, Seoul (KR)

Correspondence Address: MYERS BIGEL SIBLEY & SAJOVEC, PO BOX 37428, RALEIGH, NC, 27627, US

(73) Assignee: Samsung Electronics Co., Ltd.

(21) Appl. No.: 12/691,967

(22) Filed: Jan. 22, 2010

(30) Foreign Application Priority Data
Jan. 23, 2009 (KR) 10-2009-0006213

(51) Int. Cl. C23C 14/34

(52) U.S. Cl. 204/192.32

(57) ABSTRACT

In a semiconductor device and a method of manufacturing the semiconductor device, lower electrodes having cylindrical shapes are provided to be arranged repeatedly on a substrate. Upper surfaces of the lower electrodes are flat so that the lower electrodes have uniform heights. Supporting structures are provided between the lower electrodes to support the lower electrode, the supporting structure partially contacting outer surfaces of sidewalls of the lower electrodes that are arranged in a line. A dielectric layer is formed on surfaces of the lower electrodes and the supporting structures. An upper electrode is provided on the dielectric layer. The semiconductor device includes a capacitor having an improved capacitance. Further, the capacitor includes the support structure between the lower electrodes to prevent the adjacent lower electrodes from being short each other.

### CROSS-REFERENCE TO RELATED PATENT APPLICATION

This application claims priority under 35 U.S.C. §119 to Korean Patent Application No. 2009-6213, filed on Jan. 23, 2009 in the Korean Intellectual Property Office (KIPO), the contents of which are herein incorporated by reference in their entirety.

### BACKGROUND

1. Field

Example embodiments relate to a semiconductor device and a method of manufacturing the semiconductor device. More particularly, example embodiments relate to a semiconductor device having a capacitor and a method of manufacturing the same.

2. Description of the Related Art

A capacitor formed in a reduced unit cell still needs to provide a relatively high capacitance despite a decrease in the size of the cell. Various capacitor structures capable of increasing an effective area of an electrode included in the capacitor have been researched. For example, the capacitor structure may be a cylinder type capacitor having a lower electrode of a cylindrical shape.

However, when an aspect ratio of the lower electrode of the capacitor is increased, the lower electrode may incline or slant due to the unstable shape of the lower electrode. As a result, adjacent lower electrodes may electrically short to each other so that a bridge failure between the adjacent lower electrodes occurs.

### SUMMARY

According to some example embodiments, a semiconductor device can include lower cylindrically shaped capacitor electrodes arranged on a substrate with upper surfaces of the lower electrodes being flat so that the lower electrodes have a uniform height. Supporting structures are provided as intermediate structures between the lower electrodes, the supporting structure partially surrounding outer surfaces of sidewalls of ones of the lower electrodes that are arranged in a line. A dielectric layer is formed on surfaces of the lower electrodes and on the supporting structures. An upper electrode is provided on the dielectric layer.

In an example embodiment, the semiconductor device may further include transistors on the substrate and contact plugs being electrically connected to the transistors. The lower electrodes may be electrically connected to at least some of the contact plugs.

According to some example embodiments, a method of manufacturing a semiconductor device can be provided by forming a mold pattern including an oxide layer and a supporting layer stacked on each other on a substrate, the mold pattern having holes that are arranged repeatedly therein, forming cylindrically shaped lower electrodes on inner walls of the holes, upper surfaces of the lower electrodes being flat so that the lower electrodes have uniform heights, removing a portion of the supporting layer by performing a wet etch process to form supporting structures, wherein the supporting structure is provided between immediately adjacent ones of the lower electrodes to partially surround outer surfaces of the lower electrodes and extending therebetween over a void formed by removing the portion of the supporting layer, forming a dielectric layer on surfaces of the lower electrodes and the supporting structures, and forming an upper electrode on the dielectric layer.

In an example embodiment, forming the lower electrode may include forming an lower electrode layer on a surface of the mold pattern, forming a sacrificial layer on the lower electrode layer to fill the holes and partially removing the sacrificial layer and the lower electrode layer until an upper surface of the mold pattern is exposed, to form the lower electrode on a bottom face and sidewalls of the hole.

In an example embodiment, the lower electrode may include metal.

In an example embodiment, the supporting layer may be formed using silicon nitride by a deposition process. The supporting layer may be partially removed by a wet etch process using an etching solution including phosphorous.

In an example embodiment, forming the supporting structures may include forming a mask pattern on the lower electrodes and the mold pattern, the mask pattern extending to partially cover the lower electrodes that are arranged in a line, and selectively removing the exposed supporting layer using the mask pattern. The mask pattern may be formed using silicon oxide.

In an example embodiment, the method may further include forming transistors on the substrate and forming wirings having contact plugs, the contact plugs being electrically connected to the transistors. The lower electrodes may be electrically connected to at least some of the contact plugs.

As mentioned above, in a method of manufacturing a semiconductor device according to example embodiments, after forming lower electrodes of capacitors, supporting structures are formed to support the lower electrodes. The supporting structure may be formed by a wet etch process where the lower electrodes may not be damaged by plasma. Accordingly, the supporting structures may be formed without damaging the previously formed lower electrodes.

Further, because cave in damage due to attack is prevented during a process of forming the supporting structure, upper surfaces of the lower electrodes may be flat so that the lower electrodes have uniform heights. Accordingly, an effective area of the lower electrode may be prevented from being decreased due to the damage, to provide a capacitor having a high capacitance.

### BRIEF DESCRIPTION OF THE DRAWINGS

FIG. 1 is a cross-sectional view illustrating a capacitor in accordance with a first example embodiment.

FIG. 2 is a cross-sectional view illustrating a lower electrode and a supporting structure of a capacitor in accordance with a first example embodiment.

FIG. 3 is a perspective view illustrating a lower electrode and a supporting structure of a capacitor in accordance with a first example embodiment.

FIGS. 4 to 12 are cross-sectional views illustrating methods of manufacturing the capacitor in FIG. 1.

FIG. 13 is a perspective view illustrating a hard mask pattern on the lower electrode.

FIG. 14 is a perspective view illustrating a lower electrode that is damaged by plasma.

FIG. 15 is a cross-section view illustrating a DRAM device including the capacitor in FIG. 1.

FIG. 16 is a cross-section view illustrating methods of manufacturing the DRAM device in FIG. 15.

FIG. 17 is a cross-sectional view illustrating a DRAM device in accordance with a second example embodiment.

FIG. 18 is a plan view illustrating a capacitor in accordance with a third example embodiment.

FIG. 19 is a plan view illustrating a capacitor in accordance with a fourth example embodiment.

### DETAILED DESCRIPTION OF THE EMBODIMENTS

Various example embodiments will be described more fully hereinafter with reference to the accompanying drawings, in which some example embodiments are shown. The present invention may, however, be embodied in many different forms and should not be construed as limited to the example embodiments set forth herein. Rather, these example embodiments are provided so that this disclosure will be thorough and complete, and will fully convey the scope of the present invention to those skilled in the art. In the drawings, the sizes and relative sizes of layers and regions may be exaggerated for clarity.

It will be understood that when an element or layer is referred to as being “on,” “connected to” or “coupled to” another element or layer, it can be directly on, connected or coupled to the other element or layer or intervening elements or layers may be present. In contrast, when an element is referred to as being “directly on,” “directly connected to” or “directly coupled to” another element or layer, there are no intervening elements or layers present. Like numerals refer to like elements throughout. As used herein, the term “and/or” includes any and all combinations of one or more of the associated listed items.

It will be understood that, although the terms first, second, third, etc. may be used herein to describe various elements, components, regions, layers and/or sections, these elements, components, regions, layers and/or sections should not be limited by these terms. These terms are only used to distinguish one element, component, region, layer or section from another region, layer or section. Thus, a first element, component, region, layer or section discussed below could be termed a second element, component, region, layer or section without departing from the teachings of the present invention.

Spatially relative terms, such as “beneath,” “below,” “lower,” “above,” “upper” and the like, may be used herein for ease of description to describe one element or feature's relationship to another element(s) or feature(s) as illustrated in the figures. It will be understood that the spatially relative terms are intended to encompass different orientations of the device in use or operation in addition to the orientation depicted in the figures. For example, if the device in the figures is turned over, elements described as “below” or “beneath” other elements or features would then be oriented “above” the other elements or features. Thus, the exemplary term “below” can encompass both an orientation of above and below. The device may be otherwise oriented (rotated 90 degrees or at other orientations) and the spatially relative descriptors used herein interpreted accordingly.

The terminology used herein is for the purpose of describing particular example embodiments only and is not intended to be limiting of the present invention. As used herein, the singular forms “a,” “an” and “the” are intended to include the plural forms as well, unless the context clearly indicates otherwise. It will be further understood that the terms “comprises” and/or “comprising,” when used in this specification, specify the presence of stated features, integers, steps, operations, elements, and/or components, but do not preclude the presence or addition of one or more other features, integers, steps, operations, elements, components, and/or groups thereof.

Example embodiments are described herein with reference to cross-sectional illustrations that are schematic illustrations of idealized example embodiments (and intermediate structures). As such, variations from the shapes of the illustrations as a result, for example, of manufacturing techniques and/or tolerances, are to be expected. Thus, example embodiments should not be construed as limited to the particular shapes of regions illustrated herein but are to include deviations in shapes that result, for example, from manufacturing. For example, an implanted region illustrated as a rectangle will, typically, have rounded or curved features and/or a gradient of implant concentration at its edges rather than a binary change from implanted to non-implanted region. Likewise, a buried region formed by implantation may result in some implantation in the region between the buried region and the surface through which the implantation takes place. Thus, the regions illustrated in the figures are schematic in nature and their shapes are not intended to illustrate the actual shape of a region of a device and are not intended to limit the scope of the present invention.

Unless otherwise defined, all terms (including technical and scientific terms) used herein have the same meaning as commonly understood by one of ordinary skill in the art to which this invention belongs. It will be further understood that terms, such as those defined in commonly used dictionaries, should be interpreted as having a meaning that is consistent with their meaning in the context of the relevant art and will not be interpreted in an idealized or overly formal sense unless expressly so defined herein.

Hereinafter, example embodiments will be explained in detail with reference to the accompanying drawings.

### Embodiment 1

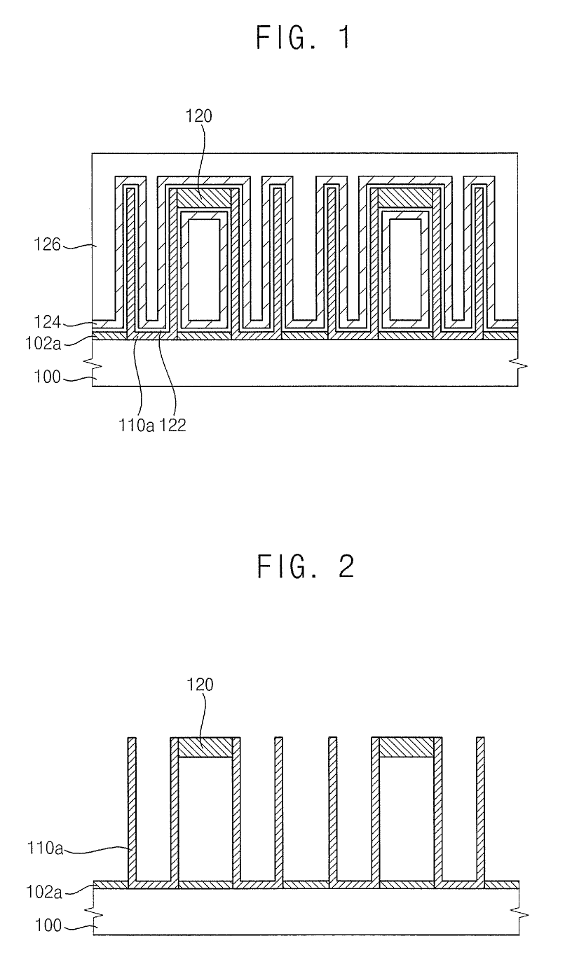

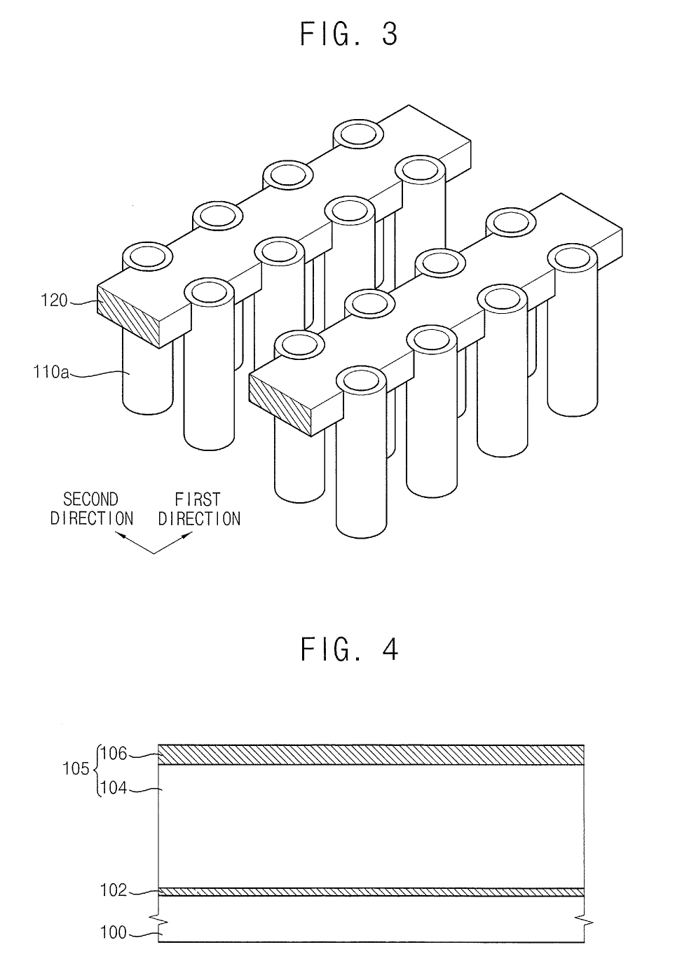

FIG. 1 is a cross-sectional view illustrating a capacitor in accordance with a first example embodiment. FIG. 2 is a cross-sectional view illustrating a lower electrode and a supporting structure of a capacitor in accordance with a first example embodiment. FIG. 3 is a perspective view illustrating a lower electrode and a supporting structure of a capacitor in accordance with a first example embodiment.

Referring to FIGS. 1 to 3, lower electrodes 110a having cylindrical shapes are provided on a substrate 100. The lower electrodes 110a have flat upper surfaces. Accordingly, the lower electrodes 110a having uniform heights may be arranged at regular intervals.

The lower electrode 110a may include a metal. For example, the lower electrode 110a may include titanium nitride, tantalum nitride, tantalum, etc. In this embodiment, the lower electrode 110a may include titanium nitride. Alternatively, the lower electrode 110a may include polysilicon.

An etch stop layer pattern 102a is provided adjacent to the lower electrode 110a on the substrate 100. The etch stop layer pattern 102a may include silicon nitride.

Supporting structures 120 are arranged between the lower electrodes 110a. The supporting structure 120 extends to contact and to partially surround outer surfaces of the lower electrodes 110a that are arranged in a line in a first direction. The supporting structure 120 may have a linear shape extending in the first direction. An upper surface of the supporting structure 120 may be coplanar with the upper surface of the lower electrode 110a.

As a distance between the lower electrodes 110a is decreased and the heights of the lower electrodes are increased, the lower electrode 110a may lean or slant to make electrical contact with an immediately adjacent lower electrode 110a so that a short failure between the immediately adjacent lower electrodes occurs. In order to reduce the occurrence of these types of failures, the supporting structures 120 are provided on the upper portions of the lower electrodes 110a to support the upper portions of the lower electrodes 110a.

The supporting structure 120 may have a linear shape extending in the first direction such that the supporting structure 120 supports the lower electrodes 110a of two immediately adjacent rows extending in a second direction perpendicular to the first direction. In this embodiment, as illustrated in FIG. 3, the supporting structure 120 of the linear shape may surround half of the outer surface of the cylindrical lower electrode 110a. The supporting structure 120 may include an insulation material. For example, the supporting structure 120 may include silicon nitride.

As illustrated in FIG. 3, because the supporting structure 120 contacts a portion of the outer surface of the lower electrode 110a, a remaining portion of the outer surface of the lower electrode 110a is not contacted by the supporting structure 120. However, the portion of the lower electrode 110a contacting the supporting structure 120 has the same shape as the remaining portion that is not contacting the supporting structure 120. That is, the outer surface of the upper portion of the lower electrode 110a may not be penetrated or damaged so that the whole upper surface of the lower electrode 110a is flat.

The supporting structure 120 may be formed using an insulating material capable of being removed by a wet etch process. For example, the supporting structure 120 may include silicon nitride.

A dielectric layer 122 is provided on the lower electrodes 110a and the supporting structures 120a. In order to increase a capacitance of a capacitor, the dielectric layer 122 may be formed using a metal oxide having a high dielectric constant. When the lower electrode 110a includes a metal material, even though the dielectric layer 122 is formed using a metal oxide having a high electric constant, a leakage current may not be increased. Accordingly, the dielectric layer 122 may be preferably formed using a metal oxide.

The dielectric layer 122 may include a zirconium oxide layer, a zirconium oxynitride layer, an aluminum oxide layer, a tantalum oxide layer, a hafnium oxide layer, etc. These may be used alone or in a combination thereof. For example, the dielectric layer 122 may be a composite layer of zirconium oxide layer/aluminum oxide layer/zirconium oxide layer or zirconium oxide layer/aluminum oxide layer/tantalum oxide layer, etc.

Alternatively, in case that the lower electrode 110a includes polysilicon, when the dielectric layer 122 is formed using a metal oxide having a high electric constant, a leakage current may be increased. Accordingly, when the lower electrode 110a includes polysilicon, the dielectric layer 122 may include a composite layer of silicon oxide layer/silicon nitride layer/silicon oxide layer (ONO).

An upper electrode 125 is provided on the dielectric layer 122. The upper electrode 125 may include a metal. When the dielectric layer 122 is formed using a metal oxide, the upper electrode 124 may include a metal or a metal nitride in order to decrease a leakage current. For example, the upper electrode 124 may include titanium nitride, titanium, tantalum nitride, tantalum, etc. In this embodiment, the upper electrode 124 may include titanium nitride. The upper electrode 124 having the metal may have a thin thickness of several hundreds of Angstroms.

A silicon germanium layer 126 is formed on the upper electrode 124. The silicon germanium layer 126 may be doped with p-type or n-type impurities.

Alternatively, the upper electrode 124 may include polysilicon.

FIGS. 4 to 12 are cross-sectional views illustrating a method of manufacturing the capacitor in FIG. 1.

Referring to FIG. 4, an etch stop layer 102 is formed on a substrate 100. The etch stop layer 102 may be formed using silicon nitride.

A mold layer 105 for forming a lower electrode is formed on the etch stop layer 102. The mold layer 105 may include a silicon oxide layer 104 and a supporting layer 106.

The mold layer 105 may have a height the same as or greater than that of the lower electrode to be formed. The silicon oxide layer 104 may be formed using BPSG, TOST, HDP, PE-TEOS, etc. In this embodiment, the silicon oxide layer 104 may be formed using PE-TEOS.

The supporting layer 106 may be formed using an insulating material having a high etch selectivity with respect to the silicon oxide layer 104. Additionally, the supporting layer 106 may be formed using a material capable of being easily removed by a wet etch process. For example, the supporting layer 106 may be formed of silicon nitride. The supporting layer 106 may be formed to be a supporting structure for supporting the lower electrode by a following process. Accordingly, the supporting layer 106 may be formed to have a thickness the same as or greater than that of the supporting structure to be formed.

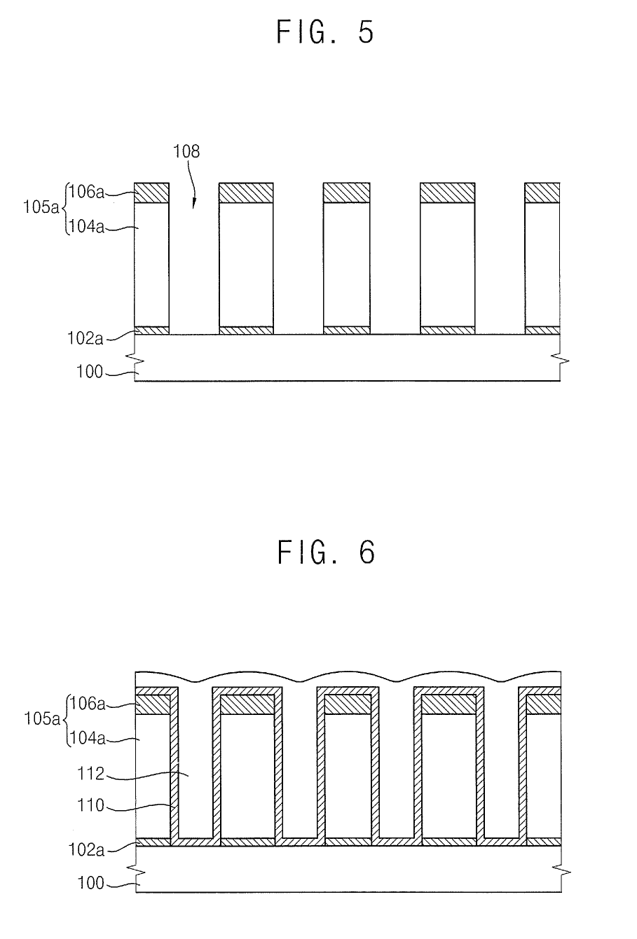

Referring to FIG. 5, the supporting layer 106 and the silicon oxide layer 104 is partially etched, and then the etch stop layer 102 is etched to form holes 108. A surface of the substrate 100 is partially exposed through bottom faces of the holes 108. The above-mentioned processes are performed to form a mold pattern 105a of an etch stop layer pattern 102a, a silicon oxide layer pattern 104a and a supporting layer pattern 106a stacked on another.

Since the lower electrodes are formed in the holes 108 by a following process, the holes 108 may be arranged at regular intervals.

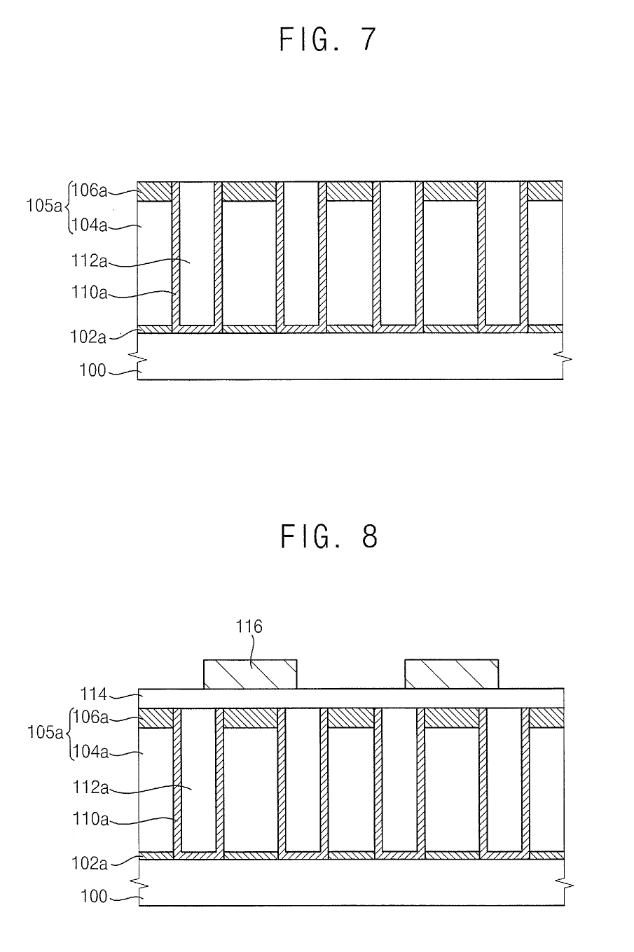

Referring to FIG. 6, a lower electrode layer 110 is formed on bottom faces and sidewalls of the holes 108 and on an upper surface of the mold pattern 105a. The lower electrode layer 110 is formed to have a relatively thin thickness so that the hole 108 is not completely filled with the lower electrode layer 110. The lower electrode 110 may be formed by a chemical vapor deposition process, an atomic layer vapor deposition process or a mechanical vapor deposition process.

The lower electrode layer 110 may include a metal material. For example, the lower electrode layer 110 may include titanium nitride, titanium, tantalum nitride, tantalum, etc. In this embodiment, the lower electrode layer 110 may be formed by depositing titanium nitride.

A sacrificial layer 112 is formed on the lower electrode layer 110 to completely fill the holes 108. The sacrificial layer 112 may be foamed using silicon oxide.

Referring to FIG. 7, the sacrificial layer 112 and the lower electrode layer 110 are planarized by a chemical mechanical polishing process until the upper surface of the mold pattern 105a is exposed. The above-mentioned process is performed to form a lower electrode 110a on the bottom face and sidewalls of the hole 108. The sacrificial layer 112 is removed to form a sacrificial layer pattern 112a only in the hole 108.

Referring to FIG. 8, a first hard mask layer 114 is formed to cover the mold pattern 105a, the sacrificial layer pattern 112a and the lower electrode 110a. The first hard mask layer 114 may be formed using a material having a high etch selectivity with respect to the supporting layer pattern 106a. The first hard mask layer 114 may be formed using silicon oxide. Examples of the silicon oxide may be BPSG, TOSZ, HDP, PE-TEOS, etc. In this embodiment, the first hard mask layer 114 may be formed using PE-TEOS.

A second mask pattern 116 is formed on the first hard mask layer 114. The second mask pattern may be formed using polymer material. Alternatively, the second mask pattern may be formed using photoresist material. Preferably, the second mask pattern 116 may be formed using the polymer material capable of being more easily removed than the photoresist pattern by an ashing and strip processes.

For example, the second mask pattern 116 may be formed using CSOH (carbon-SOH) or SOH material. The second mask pattern 116 is positioned to cover a region for a supporting structure to be formed. The second mask pattern 116 may be formed to have a width greater than that of the supporting structure.

The second mask pattern 116 may be formed over the region for the supporting structure to be formed. In this embodiment, the second mask pattern 116 may be positioned between the lower electrodes 110a to partially cover upper portions of two adjacent lower electrodes 110a that are arranged in a first direction. The second mask pattern 116 may have a linear shape to partially cover portions of the lower electrodes 110a that are arranged in a second direction perpendicular to the first direction.

Alternatively, the second mask pattern 116 may have an isolated shape to cover portions of several lower electrodes 110a that are arranged in the second direction. Accordingly, the position and the shape of the supporting structure may be determined according to the shape of the second mask pattern 116.

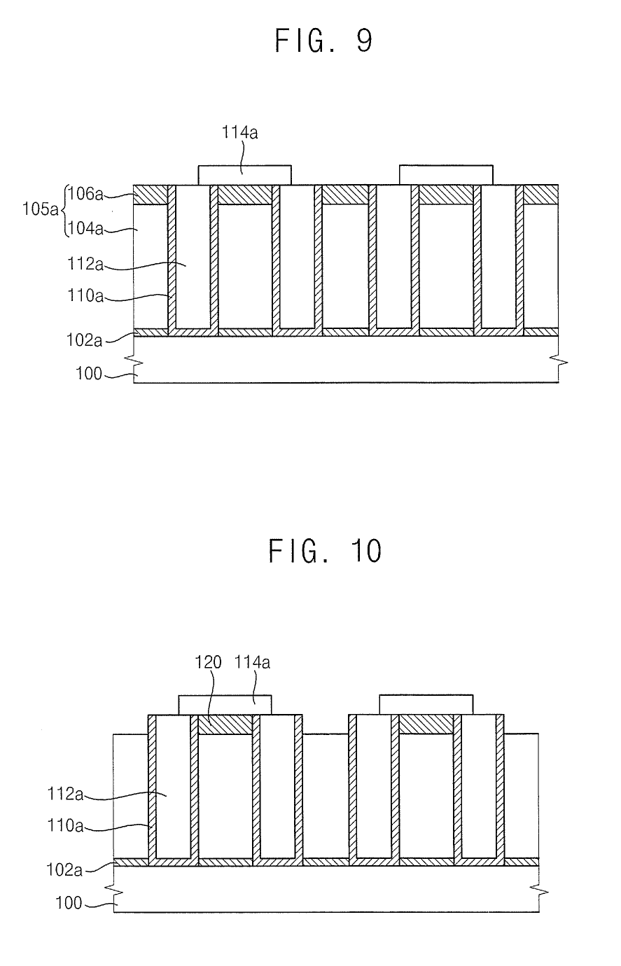

Referring to FIG. 9, the first hard mask layer 114 is etched using the second mask pattern 116 as an etching mask to form a hard mask pattern 114a. The supporting layer pattern 106a and the lower electrode 110a are partially exposed by the hard mask pattern 114a.

The second mask pattern 116 is removed from the hard mask pattern 114a. The second mask pattern 116 may be removed by an ashing and strip processes.

FIG. 13 is a perspective view illustrating the hard mask pattern on the lower electrode.

As illustrated in FIG. 13, the hard mask pattern 114a has a linear shape to cover the portions of the lower electrodes 110a that are arranged in the second direction. The hard mask pattern 114a is formed to cover sufficiently the region for the supporting structure to be formed. The hard mask pattern may be formed to have a width greater than that of the supporting structure.

Referring to FIG. 10, the portions of the supporting layer pattern 106a exposed by the hard mask pattern 114a is removed using the hard mask pattern 106a as an etching mask by a wet etch process. The wet etch process is performed such that the supporting layer pattern 106a remains only under the hard mask pattern 114a to form a supporting structure 120. The support structure is formed by the wet etch process to have a width smaller than that of the hard mask pattern 114a.

The supporting layer pattern 106a including silicon nitride may be removed by a wet etch process using an etching solution including phosphorous.

However, in case that the supporting structure is formed by performing a dry etch process using plasma, when the supporting layer pattern is etched, the lower electrode exposed by the hard mask pattern is damaged by plasma. Accordingly, the exposed portion of the lower electrode is partially etched together with the supporting layer pattern.

Referring to FIG. 11, the silicon oxide layer pattern 104a and the sacrificial layer pattern 112a of the mold pattern 105a are removed by a wet etch process. The silicon oxide layer pattern 104a and the sacrificial layer pattern 112a may be removed together by a wet etch process.

Accordingly, as illustrated in FIG. 3, an outer surface, an inner surface and an inner bottom face of the cylindrical lower electrode 110a are exposed by performing the above-processes. Additionally, the supporting structure 120 is formed to partially surround the outer surface of the upper portion of the lower electrode 110a. In this embodiment, because the supporting structure 120 is formed by a wet etch process, when the supporting layer pattern is etched, the lower electrode may not be damaged during the process to have a flat upper surface. Accordingly, an effective area of the lower electrode may not be decreased due to the formation of the supporting structure, to provide a capacitor having a high capacitance.

However, in case that the supporting structure is formed by performing a dry etch process using plasma, because the lower electrode is damaged by plasma, the upper surface of the lower electrode may not be flat.

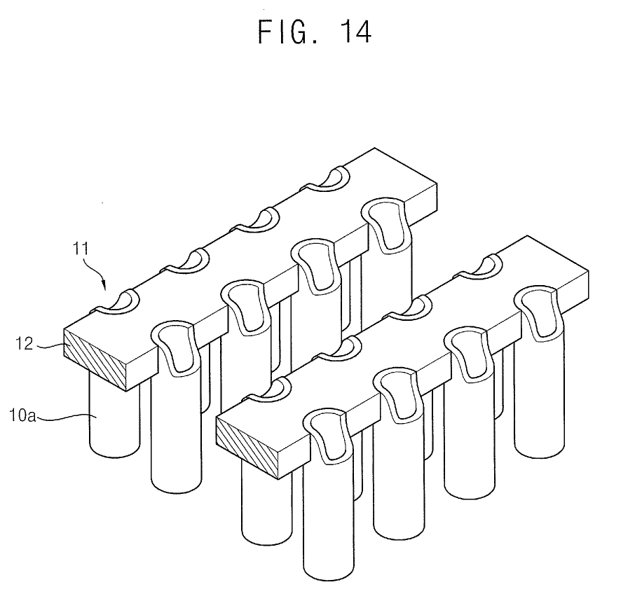

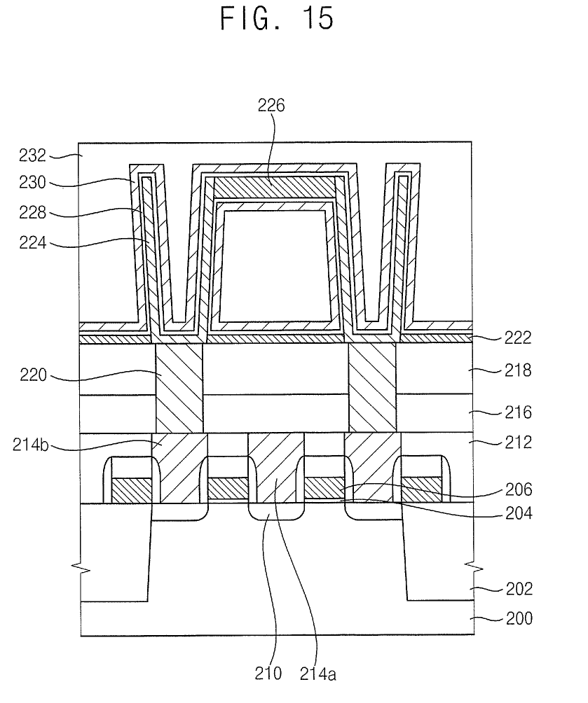

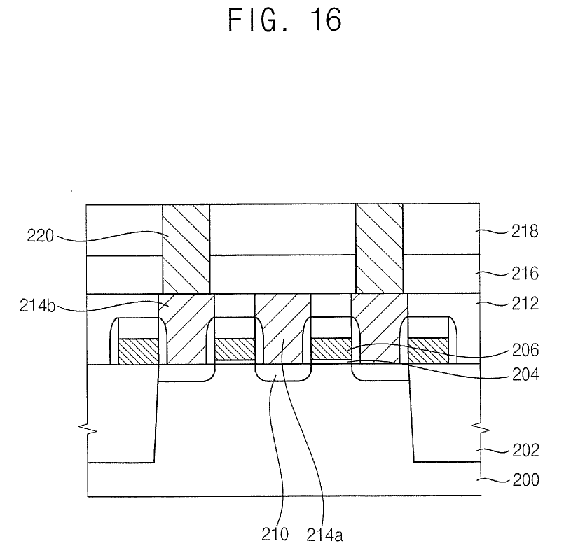

FIG. 14 is a perspective view illustrating a lower electrode that is damaged by plasma. FIG. 14 is presented for comparison with a first example embodiment.

As illustrated in FIG. 14, because an exposed lower electrode 10a is etched together during the process for forming the supporting structure 12, the upper portion of the lower electrode 10a caves in (see 11) and the upper surface of the lower electrode 10a is not be flat. Accordingly, as the upper portion of the lower electrode 10a is partially etched, an effective area of the lower electrode is decreased, so that a capacitance of a capacitor is decreased.

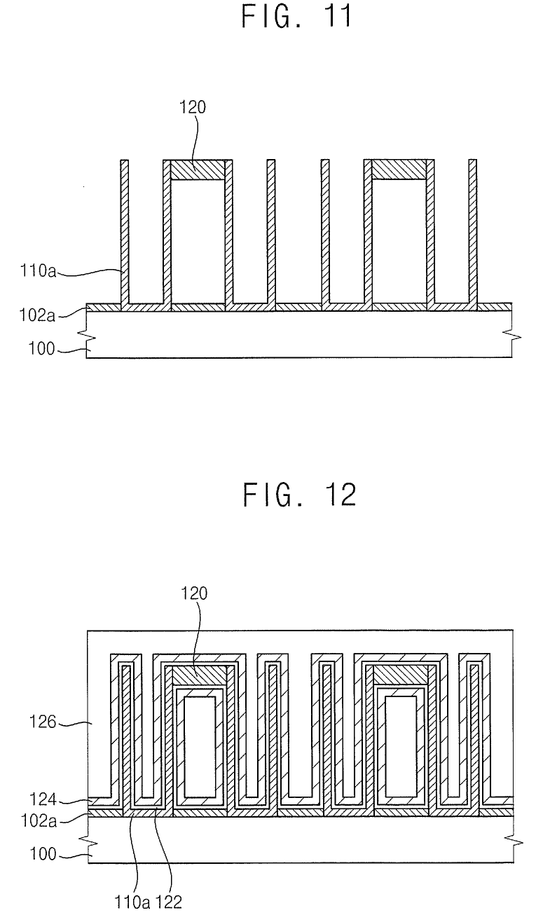

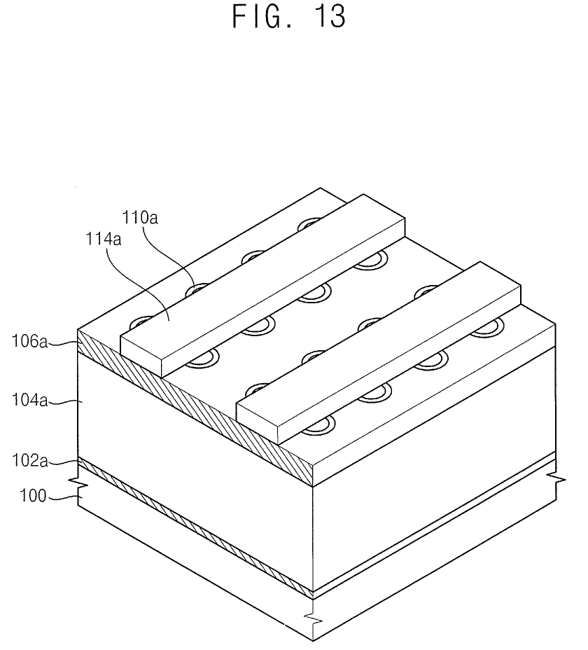

Referring to FIG. 12, a dielectric layer 122 is formed on the surface of the lower electrode 110a. The dielectric layer 122 may be formed by depositing a metal oxide having a high dielectric constant. The dielectric layer 122 may be formed by a chemical vapor deposition process or an atomic layer vapor deposition process. Examples of the metal oxide layer may be a zirconium oxide layer, a zirconium oxynitride layer, an aluminum oxide layer, a tantalum oxide layer, a hafnium oxide layer, etc. These may be used alone or in a combination thereof. For example, the dielectric layer 122 may be a composite layer of zirconium oxide layer/aluminum oxide layer/zirconium oxide layer or zirconium oxide layer/aluminum oxide layer/tantalum oxide layer, etc.

An upper electrode 124 is formed on the dielectric layer 122. When the dielectric layer 122 is formed using a metal oxide, the upper electrode 124 may be formed using a metal. For example, the upper electrode 124 may include titanium nitride, titanium, tantalum nitride, tantalum, etc. The upper electrode 124 may be formed by a chemical vapor deposition process, a physical vapor deposition process or an atomic layer vapor deposition process. The upper electrode 124 having the metal may a thin thickness of several hundreds of Angstroms.

A silicon germanium layer 126 doped with impurities is formed on the upper electrode 124. The silicon germanium layer 126 doped with impurities makes contact with the upper electrode 124 to be electrically connected to the upper electrode 124.

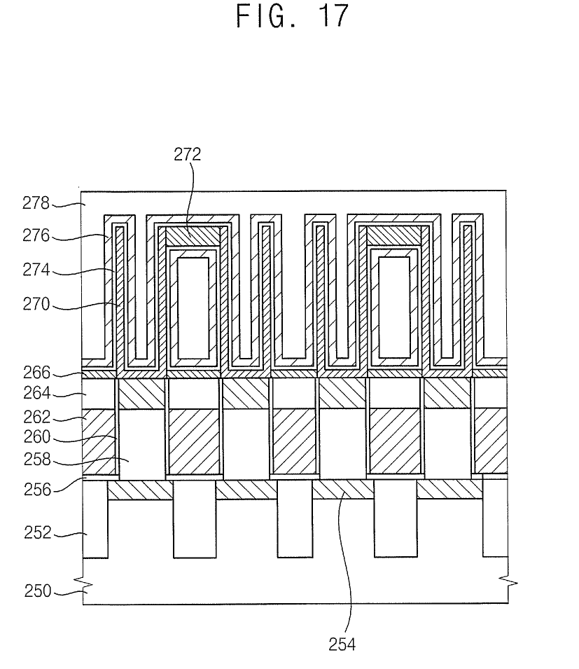

FIG. 15 is a cross-section view illustrating a DRAM device including the capacitor in FIG. 1.

Referring to FIG. 15, a substrate 200 having active regions and isolation regions is prepared. The active regions may have isolated shapes.

MOS transistors including a gate insulation layer 204, a gate electrode 206 and a source/drain 210 are formed on the active regions.

A first insulation interlayer 212 is provided to cover the MOS transistors. First and second pad contacts 214a and 214b are provided in the first insulation interlayer 212 to be connected to the source/drains 210, respectively.

A second insulation interlayer 216 is provided on the first insulation interlayer 212. Bit line contacts (not illustrated) are provided in the second insulation interlayer 216 to be connected to the first pad contacts 214a. Additionally, bit line structures (not illustrated) are provided on the second insulation interlayer 216 to contact the bit line contacts.

A third insulation interlayer 218 is provided on the second insulation interlayer 216 to cover the bit line structures. Storage node contacts 220 are provided to penetrate the third and second insulation interlayers 218 and 216 to be contacted to the second pad contacts 214b. The storage node contacts 220 are arranged at regular intervals.

The capacitor in FIG. 1 is provided on the third insulation interlayer 218 in which the storage node contact 220 is formed. An etch stop layer 222 is provided adjacent to a lower electrode 224 of a capacitor on the third insulation interlayer 218. The lower electrode 224 is arranged to contact the storage node contact 220. The capacitor includes the cylindrical lower electrode 224 contacting the storage node contact 220, a supporting structure for supporting the lower electrode 224, a dielectric layer 228 on the lower electrode 224 and an upper electrode 230 on the dielectric layer 228. Additionally, a silicon germanium layer 232 is provided to cover the upper electrode 230.

The DRAM device includes the capacitor in Embodiment 1 as illustrated in FIG. 1. Accordingly, 2 bit failure that occurs when the lower electrode of the capacitor leans or slants may be prevented. Further, a plurality of cells may be highly integrated in a relatively small lateral area.

FIG. 16 is a cross-section view illustrating a method of manufacturing the DRAM device in FIG. 15.

Referring to FIG. 16, a pad oxide layer (not illustrated) and a first hard mask layer (not illustrated) are formed on a substrate 200. The pad oxide layer and the first hard mask layer are patterned to form a pad oxide layer pattern and a first hard mask pattern. The substrate 200 is etched using the first hard mask pattern as an etching mask to form an isolation trench. An insulation layer is filled in the isolation trench and then is planarized to form an isolation pattern 202. By the processes, the substrate 200 is divided into an active region and an isolation region.

A gate insulation layer 204 and a gate electrode 206 are formed on the substrate 200. Spacers are formed on both sides of the gate electrode 206. Impurities are doped into the substrate 200 in both sides of the gate electrode 206, to form a source/drain 210. Accordingly, MOS transistors are formed on the substrate 200.

A first insulation interlayer 212 is formed on the substrate 200 to cover the MOS transistors. The first insulation interlayer 212 is partially etched to form first contact holes that respectively exposes the source/drains 210. A conductive material is filled in the first contact holes to form first and second pad contacts 214a and 214b that are connected to the source/drains 210, respectively.

A second insulation interlayer 216 is formed on the first insulation interlayer 212. The second insulation interlayer 216 is partially etched to from second contact holes (not illustrated) that respectively exposed upper portions of the first pad contacts 214a. A conductive material is filled in the second contact holes to form bit line contacts (not illustrated). Bit line structures (not illustrated) are formed on the second insulation interlayer 216 to be connected to the bit line contacts.

A third insulation interlayer 218 is formed on the second insulation interlayer 216 to cover the bit line structures. The third and second insulation interlayers 218 and 216 are partially etched to form third contact holes that respectively expose upper portions of the second pad contact 214b. Conductive material is filled in the third contact holes to form storage contacts 220.

Then, processes of manufacturing a capacitor the same as those described with reference to FIGS. 4 to 12 are performed, to form the etch stop layer 222, the capacitor and the silicon germanium layer 232 in FIG. 15. In order to form the capacitor, in a step of forming a hole of the mold pattern 105, the storage node contact 220 is exposed through a bottom face of the hole 108. Accordingly, the lower electrode 224 of the capacitor makes contact with the storage node contact 220.

### Embodiment 2

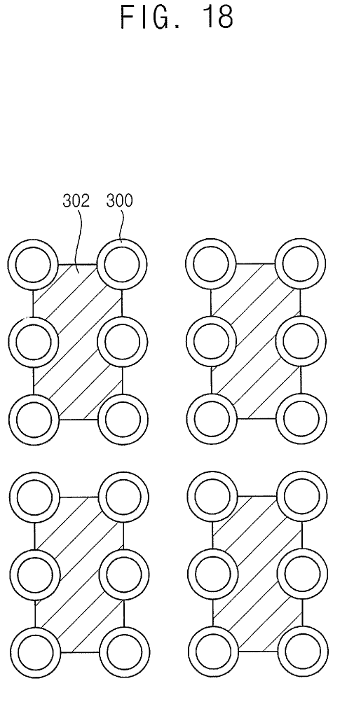

FIG. 17 is a cross-sectional view illustrating a DRAM device in accordance with a second example embodiment.

The DRAM device of the present embodiment includes the same capacitor as illustrated in FIG. 1 and has a different cell structure from the DRAM device of FIG. 15.

Referring to FIG. 17, a substrate 250 having active regions and isolation regions is provided. The active region and the isolation region may have linear shapes extending in a first direction. The active and isolation regions may be arranged alternatively each other.

A buried bit line 254 is provided in the active region of the substrate 250. Impurities are doped under a surface of the substrate 250 to be the buried bit line 254.

A single-crystalline silicon pillar 258 is provided to contact the surface of the substrate 250. A gate insulation layer 260 is provided on a surface of a sidewall of the single-crystalline silicon pillar 258. A gate electrode 262 is provided on a surface of the gate insulation layer 260. The gate electrode 262 may have a linear shape extending in a second direction perpendicular to the first direction to surround the sidewalls of the single-crystalline silicon pillars 258.

An insulation layer pattern 256 is interposed between the upper surface of the substrate 250 and a bottom surface of the gate electrode 262. Accordingly, the gate electrode 262 may be insulated from the substrate 250. An insulation interlayer 264 is provided in gaps between the gate electrodes 262. An upper surface of the insulation interlayer 264 is coplanar with an upper surface of the single-crystalline silicon pillar 258.

An impurity region is provided under the upper surface of the single-crystalline silicon pillar 258. The impurity region may be used as a source/drain.

As illustrated in the figure, a plurality of vertical pillar transistors is arranged repeatedly on the substrate.

An etch stop layer pattern 266, a capacitor and a silicon germanium layer 278 of the same structure as illustrated in FIG. 1 are provide on the impurity region and the insulation interlayer 264. The capacitor may be arranged such that a bottom surface of a lower electrode 270 makes contact with the impurity region. That is, the capacitor includes the cylindrical lower electrode 270 contacting the impurity region, a supporting structure 272 supporting the lower electrode 270, a dielectric layer 274 formed on the lower electrode 270 and an upper electrode 276 formed on the dielectric layer.

### Embodiment 3

FIG. 18 is a plan view illustrating a capacitor in accordance with a third example embodiment.

The capacitor of the present embodiment is substantially the same as in Embodiment 1 except a shape of the supporting structure.

Referring to FIG. 18, lower electrodes 300 having cylindrical shapes are provided on a substrate. The lower electrodes 300 may be arranged repeatedly. The lower electrodes 300 may have flat upper surfaces so that the lower electrodes 300 have uniform heights.

Supporting structures 302 are arranged between the lower electrodes 300 to support the lower electrodes 300. The supporting structure 302 may extend in a first direction to support sidewalls of two lower electrodes 300 adjacent in a second direction perpendicular to the first direction. As illustrated in the figure, the supporting structure 302 may have an isolated shape extending in the first direction to support at least two rows of the lower electrodes 300 arranged in the first direction. A plurality of the supporting structures 302 having the isolated shapes may be arranged in the first direction.

Although it is not illustrated in the figure, a dielectric layer is formed on the lower electrode 300 and an upper electrode is formed on the dielectric layer.

The capacitor of the present embodiment may be manufactured by performing the same processes as described with reference to FIGS. 4 to 12 in Embodiment 1 except a step of forming the hard mask pattern for patterning the support structure.

### Embodiment 4

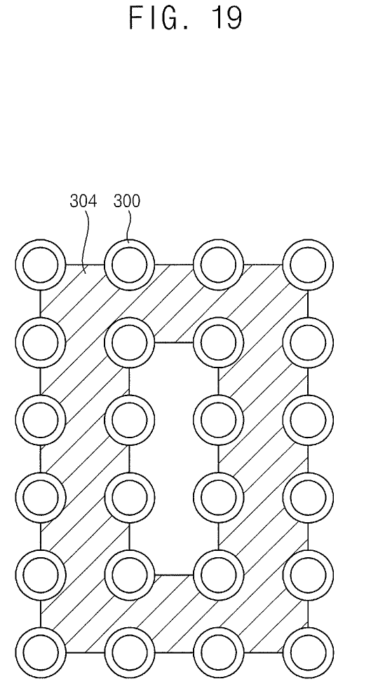

FIG. 19 is a plan view illustrating a capacitor in accordance with a fourth example embodiment.

The capacitor of the present embodiment is substantially the same as in Embodiment 1 except a shape of the supporting structure.

Referring to FIG. 19, lower electrodes 300 having cylindrical shapes are provided on a substrate. The lower electrodes 300 may be arranged repeatedly. The lower electrodes 300 may have flat upper surfaces so that the lower electrodes 300 have uniform heights.

Supporting structures 304 are arranged between the lower electrodes 300 to support the lower electrodes 300. The supporting structures 304 may extend in a first direction to respectively support sidewalls of two lower electrodes 300 adjacent in a second direction perpendicular to the first direction. Each end portion of the extending supporting structure 304 may be connected to each end portion of the adjacent supporting structure 304 in a second direction perpendicular to the first direction. Accordingly, as illustrated in FIG. 19, the whole supporting structure 304 may have a ring shape as viewed from above.

Although it is not illustrated in the figure, a dielectric layer is formed on the lower electrode 300 and an upper electrode is formed on the dielectric layer.

The capacitor of the present embodiment may be manufactured by performing the same processes as described with reference to FIGS. 4 to 12 in Embodiment 1 except a step of forming the hard mask pattern for patterning the support structure.

As mentioned above, a capacitor according to an example embodiment may have an improved high capacitance. The capacitor having a cylindrical lower electrode may be used to provide a highly integrated device.

The foregoing is illustrative of example embodiments and is to not be construed as limiting thereof. Although a few example embodiments have been described, those skilled in the art will readily appreciate that many modifications are possible in the example embodiments without materially departing from the novel teachings and advantages of the present invention. Accordingly, all such modifications are intended to be included within the scope of the present invention as defined in the claims. In the claims, means-plus-function clauses are intended to cover the structures described herein as performing the recited function and not only structural equivalents but also equivalent structures. Therefore, it is to be understood that the foregoing is illustrative of various example embodiments and is to not be construed as limited to the specific example embodiments disclosed, and that modifications to the disclosed example embodiments, as well as other example embodiments, are intended to be included within the scope of the appended claims.

1.-2. (canceled)

3. A method of manufacturing a semiconductor device, comprising:
forming a mold pattern including an oxide layer and a supporting layer stacked on each other on a substrate, the mold pattern having holes that are arranged repeatedly therein;
forming cylindrically shaped lower electrodes on inner walls of the holes, upper surfaces of the lower electrodes being flat so that the lower electrodes have uniform heights;
removing a portion of the supporting layer by performing a wet etch process to form supporting structures, wherein the supporting structure is provided between immediately adjacent ones of the lower electrodes to partially surround outer surfaces of the lower electrodes and extending therebetween over a void formed by removing the portion of the supporting layer;
forming a dielectric layer on surfaces of the lower electrodes and the supporting structures; and
forming an upper electrode on the dielectric layer.

4. The method of claim 3, wherein forming the lower electrode comprises
forming an lower electrode layer on a surface of the mold pattern;
forming a sacrificial layer on the lower electrode layer to fill the holes; and
partially removing the sacrificial layer and the lower electrode layer until an upper surface of the mold pattern is exposed, to form the lower electrode on a bottom face and sidewalls of the hole.

5. The method of claim 3, wherein the lower electrode comprises metal.

6. The method of claim 3, wherein the supporting layer comprises silicon nitride formed by a deposition process.

7. The method of claim 6, wherein the supporting layer is partially removed by a wet etch process using an etching solution including phosphorous.

8. The method of claim 3, wherein forming the supporting structures
forming a mask pattern on the lower electrodes and the mold pattern, the mask pattern extending to partially surround the lower electrodes that are arranged in a line; and
selectively removing the exposed supporting layer using the mask pattern.

9. The method of claim 8, wherein the mask pattern comprises silicon oxide.

10. The method of claim 3, further comprising
forming transistors on the substrate; and
forming wirings having contact plugs, the contact plugs being electrically connected to the transistors,
wherein the lower electrodes are electrically connected to at least some of the contact plugs.

11. A method of manufacturing a semiconductor device, comprising:
removing a portion of a supporting layer in which lower capacitor electrodes are formed to provide capacitor electrode support structures extending between uppermost portions of immediately adjacent ones of the lower capacitor electrodes over a void formed by removing the portion of the supporting layer;
forming a dielectric layer on surfaces of the lower electrodes and the supporting structures; and
forming an upper electrode on the dielectric layer.
